(19) United States
(12) Patent Application Publication
(10) Pub. No.: US 2026/0186038 A1
(43) Pub. Date: Jul. 2, 2026

(54) METHOD AND SYSTEM OF DETERMINING LINEARITY OF A POWER AMPLIFIER MODULE IN LOAD PULL MEASUREMENTS

(71) Applicant: The Education University of Hong Kong, Tai Po (CN)

(72) Inventors: Wai Yin Mung, Tai Po, N.T. (CN); Chun Yin Lai, Tai Po, N.T. (CN)

(21) Appl. No.: 19/007,822

(22) Filed: Jan. 2, 2025

(51) Int. Cl. G01R 27/32; G06N 3/08; G06N 20/00

(52) U.S. Cl. CPC G01R 27/32; G06N 3/08; G06N 20/00

(57) ABSTRACT

A computer-implemented method of determining linearity of a power amplifier module (PAM) in load pull measurements includes: receiving an input dataset including a plurality of load pull parameters; processing, by a neural network, the input dataset including the plurality of load pull parameters; and; producing an output dataset including a linearity of the PAM

### TECHNICAL FIELD

The present invention relates to a system and method of determining linearity of a power amplifier module in load pull measurements.

### BACKGROUND

Mobile front end circuits are essential components of modern wireless communication systems, such as smartphones, tablets, and other future mobile devices. Power amplifier modules (PAMs) play an important role in communication systems and are responsible for achieving high linearity and efficiency, which are essential for reliable wireless communication and the power consumption of products.

The power amplifier module (PAM) is a fully matched packaged product in the transmitter for amplification in mobile product applications. A PAM is crucial in modern wireless communication systems when providing reliable and stable wireless communication and power consumption of the end-products. For example, the 3GPP standard with low current consumption to be met, load-pull measurement of the PAM is essential for the mobile front-end impedance matching application to optimize the final product.

PAMs are typically fully matched products; thus, the PAM load pull measurement setup is utilised in the evaluation of power amplifier modules under varying load conditions. The traditional method of determining linearity in load pull measurements requires utilising a setup where the load conditions are varied and all impedance points are measured, to plot a load pull contour. Traditional measurement using all the impedance points for plotting load-pull contours is time-consuming and resource intensive.

### SUMMARY OF THE INVENTION

The present invention relates to a system and method of determining linearity of a power amplifier module in load pull measurements. In particular, the present invention relates to a method of predicting or inferring linearity in power amplifier module (PAM) load pull measurements. A PAM as a matched package is an important component in wireless communication systems. A PAM is preferred to be impedance matched so as to optimise power consumption of the overall system. Linearity is an indicator or measure of the ability of the PAM to amplify the input signal without distortion e.g., loss of signal power and/or loss of fidelity etc.

In accordance with one aspect there is provided a method of determining linearity of a power amplifier module (PAM) in load pull measurements comprising: receiving input parameters, processing the parameters by a deep neural network (DNN), outputting a predicted linearity. Optionally, the method may comprise the step of displaying the predicted linearity on a user interface e.g., a display.

In accordance with a further aspect there is provided a system of determining linearity of a power amplifier module (PAM) in load pull measurements comprising: a power amplifier module operatively coupled to a power supply, an input line of the PAM coupled to an input signal generator, an output line of the PAM coupled to an automated tuner and attenuator, wherein the automated tuner configured to set or adjust an impedance, a computing apparatus coupled to the automated tuner, wherein the computing apparatus is configured to: receive input parameters, process the parameters by a deep neural network (DNN), output a predicted linearity. The predicted linearity may be outputted by the DNN. The DNN may be stored in a memory unit of the computing apparatus and executed by a processor of the computing apparatus to process the input parameters and predict linearity of the PAM i.e., infer linearity of the PAM.

In accordance with a further aspect, there is provided a computer-implemented method of determining linearity of a power amplifier module (PAM) in load pull measurements, comprising:
receiving an input dataset comprising a plurality of load pull parameters;
processing, by a neural network, the input dataset comprising the plurality of load pull parameters; and;
producing an output dataset comprising a linearity of the PAM.

In one example the linearity of the PAM is determined by inference based on the input parameters.

The method described herein accurately infers or estimates linearity of a PAM and reduces the overall time to determine linearity of the PAM. The method can significantly reduce the time required to determine linearity of a PAM during load pull measurements and provide accurate PAM load pull contours plots.

In one example the method comprising:
feeding the output dataset comprising linearity of the PAM into a full load pull dataset, and;
plotting a load pull contour plot utilizing the output dataset and one or more of the load pull parameters from the input dataset.

In one example the neural network is a deep neural network (DNN). In one example the DNN may be a lightweight DNN. In one example the DNN is structured for use in a mobile device or in a low tier computer.

In one example the load pull parameters comprise five parameters, the five parameters are Pᵢₙ, Pₒᵤₜ, Current, VSWR and Phase, wherein:
Pᵢₙ is indicative of the input power to the PAM,
Pₒᵤₜ is indicative of the output power,
Current is the electrical current during a load pull measurement,
VSWR is a voltage standing wave ratio,
Phase is the phase of the current.

In one example the method comprising:
receiving an input dataset comprising a plurality of load pull parameters, wherein the load pull parameters are measured at varying increments of a load impedance coupled to the PAM,
processing the load pull parameters measured at each increment of the load impedance to infer a linearity, and;
outputting an output dataset comprising a linearity determined for load parameters at each increment.

In one example the method comprising presenting the plotted contour plots on a user interface for use in a mobile front end impedance matching application.

In one example the is adapted to reduce the measurement time to determine linearity by at least 40% as compared to a traditional method of determining linearity.

In accordance with a further aspect, there is provided a machine learning model for determining linearity of a power amplifier module (PAM) in load pull measurements, in particular for use in the method as disclosed earlier, comprising: a deep neural network (DNN) comprising an input layer, at least three hidden layers and an output layer.

In one example the DNN is a lightweight DNN. In one example, the lightweight DNN is configured to operate on a low tier computer or a mobile device.

In one example the DNN comprises four fully connected hidden layers.

In one example each hidden layer utilizes a ReLU activation function, and wherein the hidden layers include a descending number of units, wherein the units in each layer form a geometric sequence.

In one example the input layer includes five input units, the output layer includes one output unit, and the hidden layers include a descending number of units in successive layers.

In one example the first hidden layer comprises 128 units, the second hidden layer comprises 64 units, the third hidden layer comprises 32 units, the fourth hidden layer comprises 16 units, and; wherein each layer is fully connected.

In one example wherein the input layer utilizes a ReLU activation function, and the output layer utilizes a linear activation function.

In one example the machine learning model structure allows the network to progressively refine the most relevant features needed for accurate prediction and produces a continuous value for linearity.

In accordance with a further aspect, there is provided a computer-implemented method of training a machine-learning model for determining linearity of a power amplifier module (PAM) in load pull measurements, in particular the machine-learning model as described above, comprising:
receiving an input training dataset comprising load pull parameters from conventional load pull measurements; and
using a mean square error as a loss function, and;
applying an Adam optimizer with a 0.001 learning rate.

In accordance with a further aspect, there is provided a computer-implemented method of generating a training dataset for a machine-learning model, in particular the machine-learning model described earlier, comprising:
a) perform a sweep of input power at an initial impedance level, wherein the initial impedance is 500,
b) measure the output power,
c) determine if output power reaches a saturation power,
d) if the output power is not equal to a saturation power, then measure input power, linearity and current,
e) the input power is changed the steps b) to d) are repeated,
f) if the output power is equal to a saturation power change the impedance level and repeat the method steps a) to f).

In accordance with a further aspect, there is provided a training dataset for use in the method of training a machine-learning model as described earlier, wherein the training dataset comprising: 100 epochs with a batch size of 64.

In one example the training dataset comprises at least 100,000 data points to train the model to predict linearity.

In accordance with a further aspect, there is provided a data processing apparatus for determining linearity of a power amplifier module (PAM) in load pull measurements comprising means for carrying out the method of any one of the earlier statements.

In accordance with a further aspect, there is provided a computer program comprising instructions which, when the program is executed by a computer, cause the computer to carry out the method of any one the earlier statements.

In accordance with a further aspect, there is provided a computer-readable medium comprising instructions which, when executed by a computer, cause the computer to carry out the method of any one of the earlier statements.

In accordance with a further aspect, there is provided a system for determining linearity of a power amplifier module (PAM) in load pull measurements comprising:
an input circuit,
a PAM operatively coupled to the input circuit on the input side of the PAM,
an output circuit operatively coupled to an output side of the PAM,
a computing apparatus coupled to the output circuit, the computing apparatus comprising a processor and a memory unit, the processor being operatively coupled to the memory unit, wherein the computing apparatus is configured to:
   receive an input dataset comprising a plurality of load pull parameters;
   process the input dataset comprising the plurality of load pull parameters; and;
   produce an output dataset comprising a linearity of the PAM,
   wherein the input dataset is processed by a deep neural network (DNN), and;
   wherein the load pull parameters comprise Pᵢₙ, Pₒᵤₜ, Current, VSWR and Phase, wherein: Pᵢₙ is indicative of the input power to the PAM, Pₒᵤₜ is indicative of the output power, Current is the electrical current during a load pull measurement, VSWR is a voltage standing wave ratio, and Phase is the phase of the current.

In one example the use of the method of any one of the preceding claims for at least one of: determining linearity of a PAM circuit during load pull measurements, determining linearity of a single PAM, determining linearity of a multimode, multi band PAM.

The term “comprising” (and its grammatical variations) as used herein are used in the inclusive sense of “having” or “including” and not in the sense of “consisting only of”.

It is to be understood that, if any prior art information is referred to herein, such reference does not constitute an admission that the information forms a part of the common general knowledge in the art.

### BRIEF DESCRIPTION OF THE DRAWINGS

Embodiments of the present invention will now be described, by way of example, with reference to the accompanying drawings in which:

FIG. 1 illustrates an example 5G/4G/3G mobile front-end circuit that includes a power amplifier module (PAM).

FIG. 2 illustrates a simplified FDD-band PAM path 200 extracted from FIG. 1.

FIG. 3 illustrates an example of a system for determining linearity of a PAM (power amplifier module) during load pull measurements.

FIG. 4 illustrates an example flowchart of the automated load-pull large-signal measurement method.

FIG. 5 illustrates an example of a computer-implemented method 500 of determining linearity of a power amplifier module (PAM) in load pull measurements.

FIG. 6 illustrates an example schematic diagram of a computing apparatus used as part of a system for determining linearity of a PAM during load pull measurements.

FIG. 7 illustrates an example of a linearity prediction method.

FIG. 8 illustrates a schematic diagram of an example structure of the DNN used to determine linearity.

FIG. 9 presents the measured load-pull contours at P_{PAM}=26 dBm. At Z_{load}=50Ω, ACLR=−44 dBc, and current=450 mA.

FIG. 10 illustrates the distribution of Z_{load,1} with different ratios (5:5 to 1:9).

### DETAILED DESCRIPTION OF THE PREFERRED EMBODIMENTS

The present invention relates to system and method of determining linearity of a power amplifier module in load pull measurements. A power amplifier module (PAM) as a matched package is an important component in wireless communication system, and the PAM is preferred to be impedance-matching so as to optimize the power consumption of the overall system.

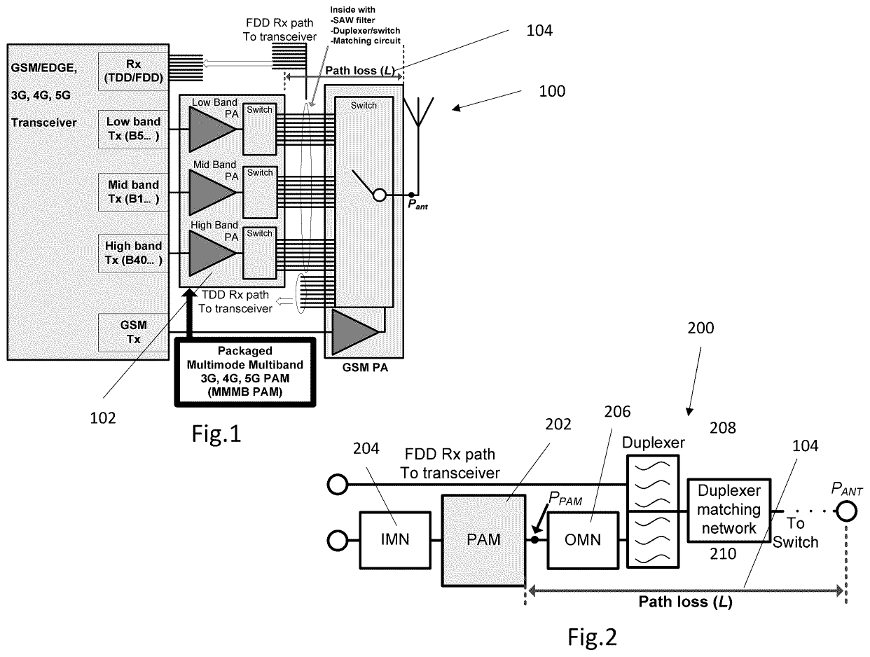

Mobile front-end circuits are essential components of modern wireless communication systems, such as smartphones, tablets, and other future mobile devices. Power amplifiers (PAs) play an important role in communication systems and are responsible for achieving high linearity and efficiency, which are important for reliable wireless communication and the power consumption of products. FIG. 1 shows an example 5G/4G/3G mobile front-end circuit 100. In this mobile application, a packaged multimode multiband power amplifier module (PAM) 102 supports 3G, 4G, and 5G standards at different frequency bands. The PAM 102 is a packaged product used for the final mobile product application, which contains digital control circuits, passive components, RF switches, and multiband power amplifiers (PAs) in a small, low-profile, and fully matched package.

Each band has an output path from the output of the PAM to the antenna power port (Pₐₙₜ). Each output path has path loss (L) 104 because of the output matching network, circuit layout, and components used. Accordingly, different impedance matching networks should be implemented at different bands in various paths. The impedance matching networks in the transmit path play an important role in managing the power levels of the input and output signals of a PAM 102, which directly affects the linearity and current consumption. The design and optimization of this impedance matching can significantly influence the performance of the transmit path, including certain factors such as Pₒᵤₜ, gain, current consumption, and linearity, which affect the overall performance of the front-end circuit. Therefore, mobile front-end impedance matching is required to optimize the final mobile product by meeting the 3GPP standard with low current consumption.

FIG. 2 illustrates a simplified FDD-band PAM path 200 extracted from FIG. 1. The input matching network (IMN) 204 and the output matching network (OMN) 206 are connected to the input and output of the PAM 202, respectively. The FDD band PAM path may also include duplexer 208 and a duplex matching network 210 that is connected to the duplex and adapted to match impedance or power draw or other parameters of the duplexer 208.

The purpose of the IMN 204 is to ensure that the input of the PAM 202 is the output of the transceiver for maximum power delivery. The OMN 206 is used to optimize the PAM performance with low current consumption and an acceptable adjacent channel leakage power ratio (ACLR) to meet the 3GPP standard. The matching network at the duplexer is sometimes required to optimize the Rx path. In TDD, the duplexer is replaced by the Tx/Rx switch. The matching network is also reserved at the switch for Rx path optimization. The delivered power (P_{PAM}) from the PAM 202 in mobile front-end applications is normally lower than the maximum power (Pₘₐₓ) of the evaluation board in the datasheet. This specified power (Pₘₐₓ) is defined to verify the PA performance under selected modulated test signals. The best power-added efficiency and ACLR result will be at Pₘₐₓ to meet the standard. This required P_{PAM} in the final product depends on L from the PAM output to the Pₐₙₜ. The load-pull contours are provided by the PA manufacturers, which include the current, linearity, and gain at different Pₒᵤₜ and output impedances. The desired performance is then achieved by the OMN. The circuits of FIG. 1 and FIG. 2 known in the art and represent known PAM module circuits.

PAMs are typically already fully matched products; thus, the PAM load-pull measurement setup is utilized in the evaluation of PAM under varying load conditions for mobile applications. The setup includes the PAM as a device under test (DUT), which is mounted on the circuit board, and its output is connected to the tuner. The tuner alters the load impedance presented to the DUT, and an automated large-signal measurement is conducted. The gain, current, and linearity are measured at different Pₒᵤₜ and load impedances, and the current and linearity contours are plotted for performance optimization in the mobile front-end circuit. The measurement time of this load-pull large-signal measurement depends on the number of impedances, the required Pₒᵤₜ, and the equipment used, which typically requires several hours. A number of neural network approaches or generative adversarial network approaches have been tried to determine load pull contours and, in some cases linearity of PAMs. These approaches require time intensive training processes and require considerable computational costs and processing resources.

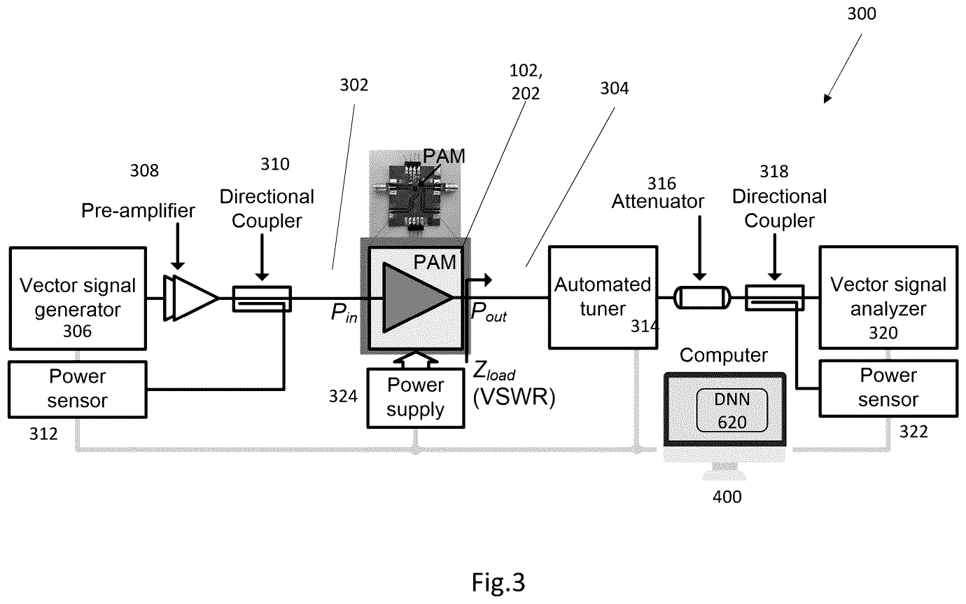

FIG. 3 illustrates an example of a circuit that is used to perform load pull measurements. FIG. 3 illustrates an example of a system 300 for determining linearity of a PAM (power amplifier module) 102, 202 during load pull measurements.

In one example the system 300 for determining linearity of a power amplifier module (PAM) in load pull measurements comprising: an input circuit 302, a PAM 102, 202 operatively coupled to the input circuit 302 on the input side of the PAM 102, 202, and; an output circuit 304 operatively coupled to an output side of the PAM 102, 202. The system 300 further comprising a computing apparatus 600 coupled to the output circuit 304. The computing apparatus 600 comprising a processor 602 and a memory unit and the processor 602 being operatively coupled to the memory unit. The memory unit may comprise one or more of ROM 604, RAM 606 or other disk drives 608. The processor 602 may be operatively coupled to each of the one or more ROM 604, RAM 606, or disk drives 608.

The system 300 may be conventional load pull, large signal measurement setup for a packaged device such as for example a PAM 102, 202. The PAM 102, 202 is mounted on a circuit board in this setup. The output impedance (Z_{load}) of the PAM corresponds to the pad of the PAM package on the circuit board. Different Z_{load} values were found and measured via a VNA.

Referring to FIG. 3, the system 100 comprises vector signal generator 306 coupled to a pre amplifier 308 which is connected to a directional coupler 310. The system 300 further comprises a power sensor 312. The vector signal generator 306, the pre amplifier 308 and the directional coupler 310 may be coupled in series as shown in FIG. 3, and together define the input circuit 302. The system 300 also comprises an automated tuner 314 which is coupled to an attenuator 316. A second directional coupler 318 is connected to the attenuator 316 on one side and to a vector signal analyser 320 on the other side. A second power sensor 322 may be coupled to the directional coupler. The automated tuner 314, attenuator 316, second directional coupler 318 and the vector signal analyser 320 are coupled in series and define the output circuit 304.

The system 300 comprises a computing apparatus 600 that is coupled to the vector signal analyser 320 and adapted to receive signals from the vector signal analyser 320. The computing apparatus 300 may also be connected to the power sensors 312, 322 and the automated tuner 314. The system 300 may include a power supply 324 that supplies power to the PAM 102, 202 and is also coupled to the computing apparatus.

The computing apparatus 600 may be configured to: receive an input dataset comprising a plurality of load pull parameters, process the input dataset comprising the plurality of load pull parameters, produce an output dataset comprising a linearity of the PAM, wherein the input dataset is processed by a deep neural network (DNN), and; wherein the load pull parameters comprise Pᵢₙ, Pₒᵤₜ, Current, VSWR and Phase, wherein: Pᵢₙ is indicative of the input power to the PAM, Pₒᵤₜ is indicative of the output power, Current is the electrical current during a load pull measurement, VSWR is a voltage standing wave ratio, and Phase is the phase of the current.

In one example the neural network is a deep neural network (DNN) 620. The DNN 620 may be 620 may be executed by the processor 602 and may be stored in a memory unit of the computing apparatus. The DNN 620 may be trained to determine an output dataset comprising linearity measure. The DNN 620 may be trained to process one or more load pull parameters that are input to the DNN and output a linearity or a parameter indicative of linearity. The linearity is an indication of the ability of the PAM to amplify the input signal without distortion. In one example the DNN 620 may be a lightweight DNN. In one example the DNN 620 is structured for use in a mobile device or in a low tier computer. The DNN 620 may be used in the testing phase of a PAM for load pull measurements.

In one example the system 300 may be used for at least one of: determining linearity of a PAM circuit during load pull measurements, determining linearity of a single PAM, determining linearity of a multimode multi band PAM.

This automated tuner 314 acts as the OMN 206 of FIG. 2. An automated test equipment program must be integrated into this system to enhance its speed performance and precision. The tuner 314 can be moved or incremented to a specific impedance, and a general large-signal measurement was conducted. This process facilitated the collection of varying Pₒᵤₜ results at different Z_{load} components adjusted by the automated tuner 314. At each power level, the key parameters, such as gain, current, and linearity, were measured, providing a comprehensive analysis of the system performance. The measured load-pull data were subsequently utilized to plot different contours. In the context of mobile applications, the front-end supports APT in the PAM. Consequently, the final mobile performance can be tuned by different voltages and bias currents at different power levels. The load-pull large-signal measurement is also required to serve different voltages and bias currents. Different bands of PAs have different gains, currents, and linearity contours for current and linearity at different powers under varying bias conditions. Therefore, a large and time-consuming measurement is required to complete the characterization and verification.

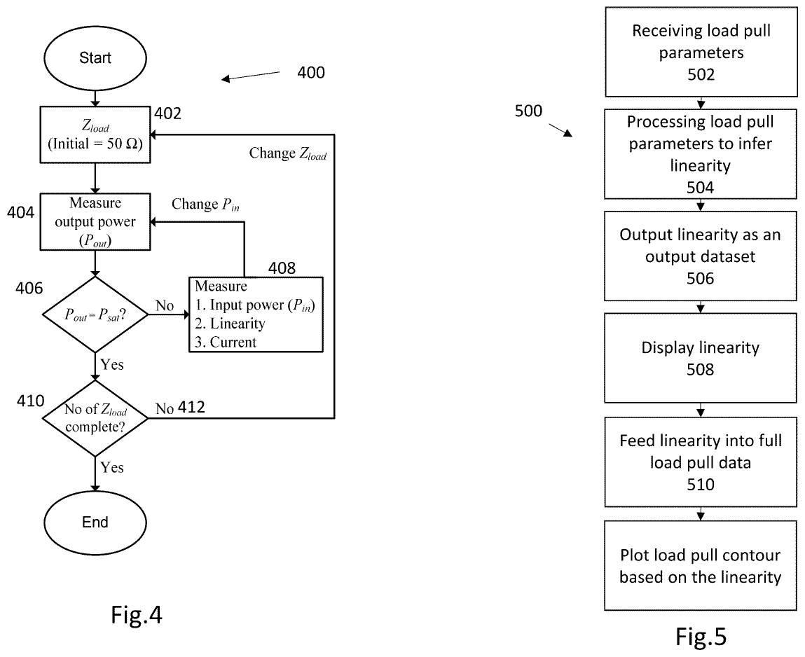

FIG. 4 illustrates an example flowchart of the automated load-pull large-signal measurement method 400. In the method 400 an input power (Pᵢₙ) sweep with different impedances is conducted at step 402. Fixed power measurement can also be used when needed. Step 404 comprises measuring output power Pₒᵤₜ. Step 406 comprises comparing the output power Pₒᵤₜ with a saturation power Pₛₐₜ. At step 408 before the Pₒᵤₜ reaches saturation power Pₛₐₜ, i.e., where an increase in Pᵢₙ does not result in a discernible increase in Pₒᵤₜ, key load pull parameters are recorded. The input power may be changed and steps 404 and 406 may be repeated across the entire input power range until the output power is saturated. If the output power reaches saturation power the method proceeds to step 410. At step 410 the method determines if the load impedance has been completed. If no, then at step 412 Z_{load} will be changed by the automated tuner for another power sweep measurement. The Z_{load} may be incremented at predefined increments and the process 400 may be repeated. If at step 410 the impedance sweep is complete, then the method 400 terminates or is ended.

Table I shows each parameter measured by different types of equipment and the measurement time of every parameter on the basis of the model used in this work. In the large-signal measurement, Pᵢₙ, linearity, and current are measured by different types of equipment; therefore, they can take the result simultaneously. Table I shows that the linearity measurement requires the most time to complete because the vector signal analyser (VSA) takes time for the power spectral measurement via the fast Fourier transform.

TABLE I
EQUIPMENT AND MEASUREMENT TIME
USED FOR EACH KEY PARAMETER

| | | | Measured time |
|---|---|---|---|
| Parameters | Equipment | Model | (millisecond) |
| Pₒᵤₜ | Power | R&S ®NRP-Z11 | 10 |
| | sensor | | |
| Pᵢₙ | Power | R&S ®NRP-Z11 | 10 |
| | sensor | | |
| Linearity | VSA | R&S ®CMW600 | 80 |
| Current | Power | R&S ®NGMO | 10 |
| | supply | | |

As shown in Table I, the linearity measurement time is 80 ms, which dominates the measurement of three key parameters. By eliminating the linearity measurement time, the total measurement time can be reduced from 80 to 10 ms, corresponding to a reduction in measurement time of 88% at each power point. The load-pull large-signal measurement implies that some relationships may exist between load-pull data parameters, including Pᵢₙ, Pₒᵤₜ, Z_{load} (VSWR and phase), and current and linearity. If linearity correlates with other parameters, then the relationship can be inferred mathematically.

In order to speed up the linearity prediction the computing apparatus is configured to execute a computer-implemented method of determining linearity of a power amplifier module (PAM) in load pull measurements, comprising: receiving an input dataset comprising a plurality of load pull parameters; processing, by a neural network, the input dataset comprising the plurality of load pull parameters; and; producing an output dataset comprising a linearity of the PAM. In one example the linearity of the PAM is determined by inference based on the input parameters.

The method described herein accurately infers or estimates linearity of a PAM and reduces the overall time to determine linearity of the PAM. The method can significantly reduce the time required to determine linearity of a PAM during load pull measurements and provide accurate PAM load pull contours plots.

In one example the neural network is a deep neural network (DNN). In one example the DNN may be a lightweight DNN. In one example the DNN is structured for use in a mobile device or in a low tier computer.

FIG. 5 illustrates an example of a computer-implemented method 500 of determining linearity of a power amplifier module (PAM) in load pull measurements. The method 500 comprises multiple steps that may be repeated. Step 502 comprises receiving an input dataset that includes one or more load pull parameters. The load pull parameters may be defined for a particular PAM or may be extracted by applying an appropriate method e.g., method 400 as described earlier.

In one example the load pull parameters comprise five parameters, the five parameters are Pᵢₙ, Pₒᵤₜ, Current, VSWR and Phase, wherein: Pᵢₙ is indicative of the input power to the PAM, Pₒᵤₜ is indicative of the output power, Current is the electrical current during a load pull measurement, VSWR is a voltage standing wave ratio, and Phase is the phase of the current.

Step 504 comprises processing the load pull parameters by the DNN 620. The DNN may be trained to process the five input load pull parameters. Step 506 comprises outputting a linearity based on processing the input load pull parameters. In one example, the DNN may apply regression or a regression prediction process to predict the linearity. The linearity measure may be a numerical number that can be used in load pull measurements. The linearity measure may be used to determine the suitability of the PAM.

Optionally the method 500 may comprise the step of displaying on the display 612 the linearity measure at step 508. The method 500 may optionally also comprise the step of feeding the predicted or determined linearity into the full load pull data at step 510. Step 512 comprises plotting a load pull contour based on the full load pull data that includes the predicted linearity by the DNN 620.

The method 500 described herein accurately infers or estimates linearity of a PAM and reduces the overall time to determine linearity of the PAM. The method can significantly reduce the time required to determine linearity of a PAM during load pull measurements and provide accurate PAM load pull contours plots. The method 500 may be executed by the computing apparatus 600. In particular, the method 500 may be executed by the DNN 620 that is implemented by the computing apparatus 600 and executed by the processor 602. The method 500 may be repeated for various input load pull parameters.

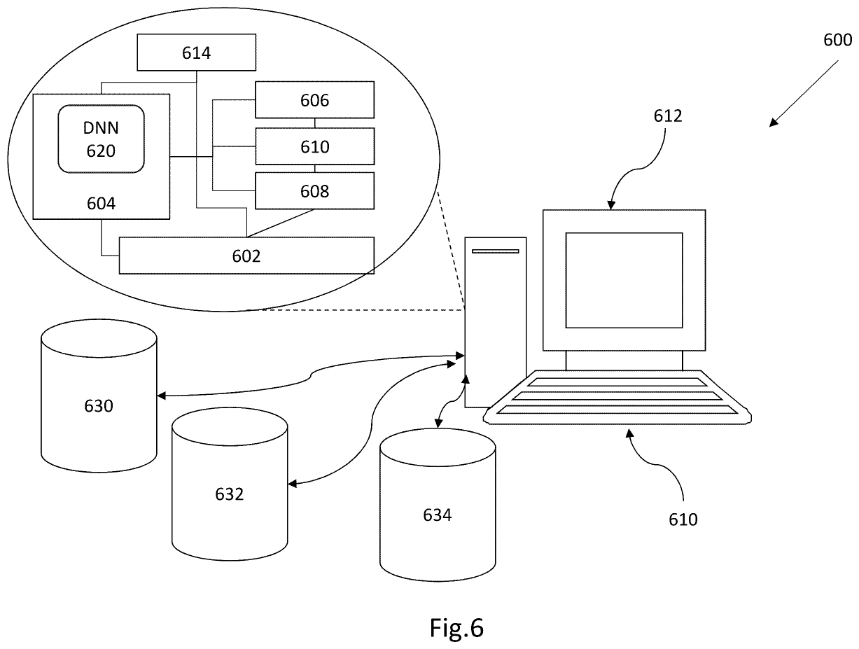

FIG. 6 illustrates an example schematic diagram of a computing apparatus 600. The computing apparatus may be implemented by any computing architecture, including portable computers, tablet computers, stand-alone Personal Computers (PCs), smart devices, Internet of Things (IOT) devices, edge computing devices, client/server architecture, “dumb” terminal/mainframe architecture, cloud-computing based architecture, or any other appropriate architecture. The computing device may be appropriately programmed to implement the invention.

Aspects of the systems and methods described above may be operable on any type of general purpose computer system or computing apparatus, including, but not limited to, a desktop, laptop, notebook, tablet, smart television, gaming console, or mobile device.

As shown in FIG. 1 there is a shown a schematic diagram of a computing apparatus 600 which is arranged to be implemented as an example embodiment of a system for determining linearity of a power amplifier module (PAM) during load pull measurements.

In this example form the computing apparatus 600 comprises suitable components necessary to receive, store and execute appropriate computer instructions. The components may include a processor 602 (i.e., a processing unit), including Central Processing Unit (CPU), Math Co-Processing Unit (Math Processor), Graphic Processing Unit (GPUs) or Tensor processing unit (TPUs) for tensor or multi-dimensional array calculations or manipulation operations or a microprocessor, read-only memory (ROM) 604, random access memory (RAM) 606, and input/output devices such as disk drives 608, input devices 610 such as an Ethernet port, a USB port, etc.

Optionally the computing apparatus may comprise a display 612. The display 612 may include a liquid crystal display, a light emitting display or any other suitable display. The linearity determined by the DNN 620 may be presented on the display or load pull contours using the linearity may be presented on the display 612.

The computing apparatus 600 may include instructions that may be included in ROM 604, RAM 606 or disk drives 608 and may be executed by the processor 602. There may be provided a plurality of communication links 614 which may variously connect to one or more computing devices such as a server, personal computers, terminals, wireless or handheld computing devices, Internet of Things (IoT) devices, smart devices, edge computing devices. At least one of a plurality of communications link may be connected to an external computing network through a telephone line or other type of communications link.

The computing apparatus 600 may include storage devices such as a disk drive 608 which may encompass solid state drives, hard disk drives, optical drives, magnetic tape drives or remote or cloud-based storage devices. The computing apparatus 600 may use a single disk drive or multiple disk drives, or a remote storage service. The server 100 may also have a suitable operating system which resides on the disk drive or in the ROM of the computing apparatus. The computing apparatus may further comprise one or more databases adapted to store one or more pieces of data. For example, the computing apparatus 600 may include a database 630 of datapoints collected from conventional load pull measurements. The database 630 may store training data for the DNN 620. The computing apparatus 600 may further comprise a linearity output database 632 where predicted linearity measures or values may be stored. Optionally, the computing apparatus 600 may further comprise a testing or verification database 634 that is adapted to store test data or verification data to test and verify the performance of the DNN 620.

The computing apparatus 600 may also provide the necessary computational capabilities to operate or to interface with a machine learning network, such as a neural networks, to provide various functions and outputs. The neural network may be implemented locally, or it may also be accessible or partially accessible via a server or cloud-based service. The machine learning network may also be untrained, partially trained or fully trained, and/or may also be retrained, adapted or updated over time. The computing apparatus may comprise one or more GPUs being operatively coupled to the CPU (i.e., processor). The computing apparatus 600 may comprise additional hardware elements operatively coupled to the CPU and/or the GPU to provide the computing apparatus components needed to implement a machine learning network or machine learning model. The learning network or model may be stored in a memory unit e.g., ROM 604.

The system and method for determining linearity of a PAM (e.g., PAM 102, 202) during load pull measurements may be used for any one or more of: determining linearity of a PAM circuit during load pull measurements, determining linearity of a single PAM, determining linearity of a multimode, multi band PAM.

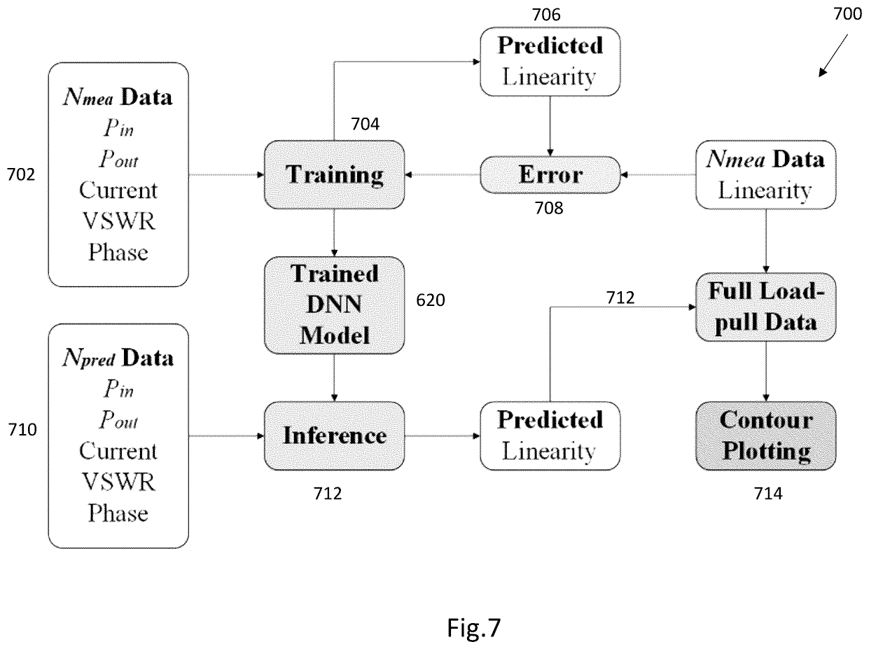

The lightweight DNN 620 by using these five parameters as the network inputs for each PAM is trained to predict linearity, thereby minimizing the need for conventional linearity measurement. The DNN 620 is expected to train quickly and provide accurate predictions. The DNN 620 is a lightweight DNN and therefore can train quickly as compared to other complex neural networks. This method still requires the modulated signal and the load-pull measurement to gather load-pull data points. The total number of load-pull data points (N) for the load-pull contour plots is given by:

$$N = {N}_{m e a} + {N}_{pred}$$

where Nₘₑₐ represents the number of data points collected from conventional load-pull measurements via the first set of load impedances, Z_{load,1}, and N_{pred} represents the number of data points, excluding linearity, measured from conventional load-pull measurements via the second set of load impedances, Z_{load,2}. The linearity of N_{pred} is predicted via a DNN trained on the Nₘₑₐ data points. FIG. 7 illustrates an example of a linearity prediction method 700.

Method 700 commences at step 702 that comprises receiving Nₘₑₐ data that includes linearity and is generated by a conventional load pull measurement process. The Nₘₑₐ data is used to train the DNN at step 704. The training process may generate a predicted linearity at step 706. An error determination is done at step 708. The error is generated by comparing the predicted linearity and the known Nₘₑₐ linearity at step 708. Step 710 comprises receiving N_{pred} data that is the input data. The input data includes five load pull parameters which are Pᵢₙ, Pₒᵤₜ, Current, VSWR and Phase. Step 712 comprises inferring a linearity using the trained DNN 620. Step 714 comprises feeding the predicted linearity into the full load pull dataset. Step 716 comprises plotting contour plots to characterise the performance of a PAM, and optionally determine suitability of the PAM in mobile circuits.

In one example a machine learning model, in particular for use in the method as disclosed earlier, comprising: a deep neural network (DNN) comprising an input layer, at least three hidden layers and an output layer. In one example the DNN is a lightweight DNN. In one example, the lightweight DNN is configured to operate on a low tier computer or a mobile device.

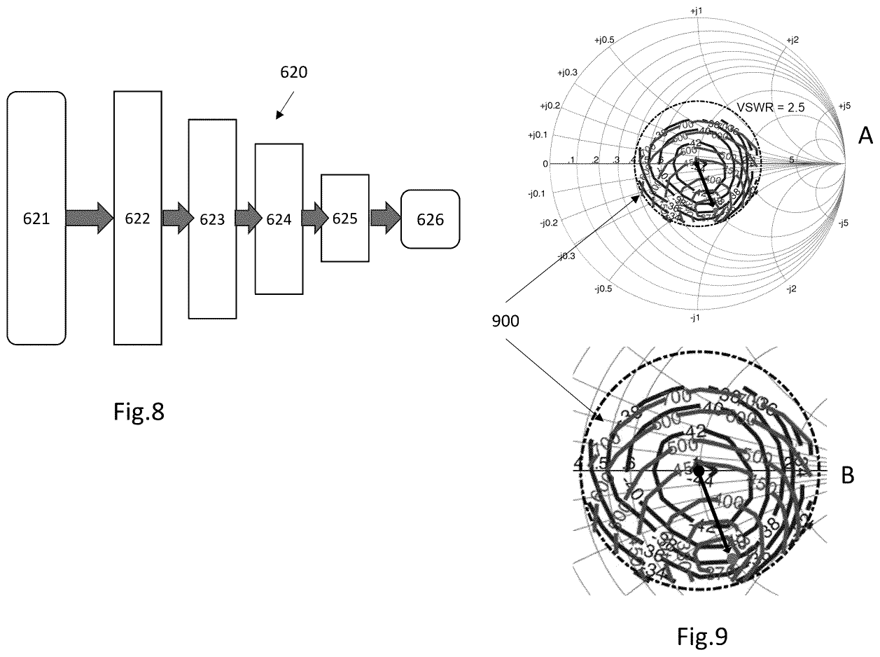

FIG. 8 illustrates a schematic diagram of an example structure of the DNN 620. FIG. 8 is an indicative representation of the DNN structure. The DNN 620 comprises an input layer 621, four hidden layers 622, 623, 624, 625 and an output layer 626 The DNN comprises four fully connected hidden layers 622-625. Rach hidden layer utilizes a ReLU activation function. The hidden layers include a descending number of units (i.e., neurons), wherein the units in each layer form a geometric sequence. In one example the input layer 621 includes five input units, the output layer 626 includes one output unit, and the hidden layers 622-625 include a descending number of units in successive layers. In one example the first hidden layer 622 comprises 128 units, the second hidden layer 623 comprises 64 units, the third hidden layer 624 comprises 32 units, the fourth hidden layer 625 comprises 16 units, and; wherein each layer is fully connected.

The input layer 625 utilizes a ReLU activation function and the output layer 626 utilizes a linear activation function. The DNN structure allows the network (i.e., DNN 620) to progressively refine the most relevant features needed for accurate prediction and produces a continuous value for linearity.

The DNN is designed with five input parameters: Pᵢₙ, Pₒᵤₜ, current, VSWR, and phase. These inputs are processed via a series of fully connected layers with ReLU activation functions, which are selected for their ability to introduce nonlinearity and enable the network to learn complex patterns in the data faster. The decreasing number of units in successive layers (128, 64, 32, and 16) allows the network to progressively refine the most relevant features needed for accurate prediction. The final output layer uses a linear activation function to produce a continuous value for linearity. This structure balances model complexity and computational efficiency, which can facilitate rapid training and accurate linearity predictions. The details of the DNN structure are shown in Table II below

TABLE II
DNN STRUCTURE FOR LINEARITY PREDICTION

| Layer | Number of units | Activation Function |
|---|---|---|
| Input layer | 5 | ReLU |
| Fully-connected layer | 128 | ReLU |
| Fully-connected layer | 64 | ReLU |
| Fully-connected layer | 32 | ReLU |
| Fully-connected layer | 16 | ReLU |
| Output Layer | 1 | Linear |

A dataset was collected to verify the relationships among the load-pull data parameters. This dataset is also utilized to verify the proposed method and system for determining linearity. A commercial PAM operating at 2.35 GHZ (Band 40) was tested via a modulated signal (QPSK/10 MHz/12RB). Accordingly, the ACLR at −10 MHz was selected as a linearity indicator. The Pₘₐₓ was approximately 28 dBm at Z_{load}=50Ω, current=580 mA, and ACLR=−38 dBc, which is the maximum allowable linearity in mobile applications. A total of 2,850 impedance points were selected for the large-signal load-pull measurement with the ACLR results, and a total of 106,624 data points were collected (e.g., using the method in FIG. 4). This work assumes that the PAM was used in FIG. 1 and that L was approximately 3 dB. According to the output power at Pₐₙₜ is 23 dBm; thus, the P_{PAM} is 26 dBm (23 dBm+3 dB). FIG. 9 presents the measured load-pull contours at P_{PAM}=26 dBm. At Z_{load}=50Ω, ACLR=−44 dBc, and current=450 mA, sufficient ACLR was utilized to lower the current consumption. Therefore, the OMN in FIG. 1 should be tuned to 50-40 j Ω for a lower current (370 mA) with maximum allowable linearity (−38 dBc). This impedance matching is important in mobile front-end applications to optimize the overall performance of the mobile system. Plot A in FIG. 9 illustrates the load pull contour 900 with VSMR circle=2.5 and plot B illustrates a zoomed in plot 900.

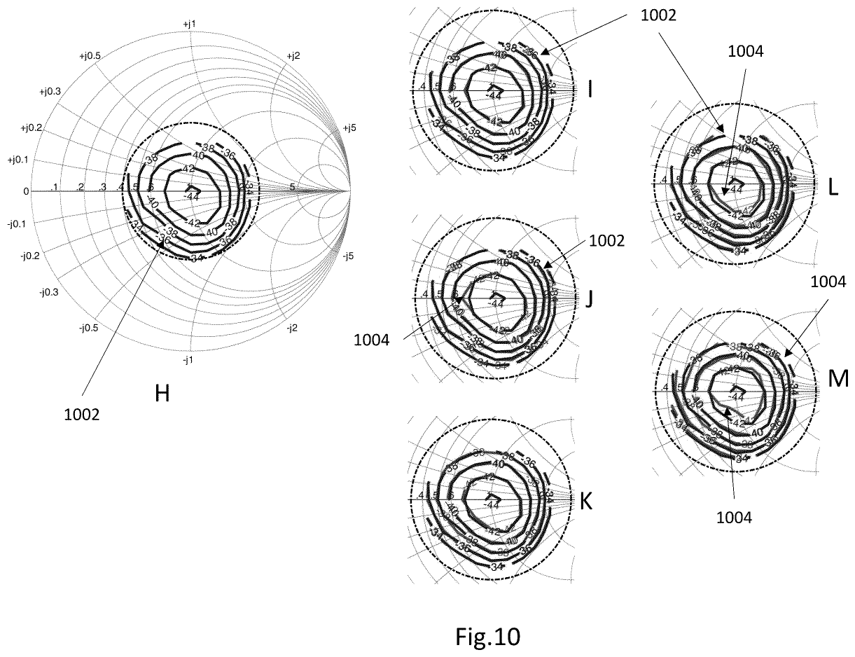

FIG. 10 shows the distribution of Z_{load,1} with different ratios (5:5 to 1:9). The ratio may indicate a ratio of training data: testing data (i.e., verification data). The different ratios of data were used to test and verify the DNN based prediction method.

In reference to the concept of the proposed method, Z_{load,1} is a training set for measuring the parameters of Nₘₑₐ to train a DNN. Z_{load,2} is an inference set for measuring load pull data without linearity (N_{pred}), which is then passed to the trained DNN 620 to predict the linearity of N_{pred}. The accuracy of the predicted linearity in N_{pred} can be evaluated after training machine learning, which requires a training set to train a machine learning model and a testing set to evaluate its performance on unobservable data. The collected dataset is divided into two sets based on Z_{load}, representing Nₘₑₐ from Z_{load,1} and N_{pred} from Z_{load,2}. Nₘₑₐ is the training set, and Z_{load,2} is the testing set. Five dataset divisions based on Z_{load,1}:Z_{load,2} ratios (5:5 to 1:9) were evaluated to determine the minimum Nₘₑₐ required to train an accurate DNN. Details of each subset are shown in Table III.

TABLE III
SIZES OF ALL DATASETS FOR METHOD VERIFICATION

| | | | | | No. of N | | |
|---|---|---|---|---|---|---|---|
| | | | | | Nₘₑₐ | N_{pred} | |
| | Ratio | No. of Z_{load} | | | from | from | |
| Dataset | Z_{load, 1}:Z_{load, 2} | Z_{load, 1} | Z_{load, 2} | Total | Z_{load, 1} | Z_{load, 2} | Total |
| Dataset 1 | 5:5 | 1,425 | 1,425 | 2,850 | 53,334 | 53,290 | 106,624 |
| Dataset 2 | 4:6 | 1,140 | 1,710 | 2,850 | 42,430 | 64,194 | 106,624 |
| Dataset 3 | 3:7 | 855 | 1,995 | 2,850 | 32,043 | 74,581 | 106,624 |
| Dataset 4 | 2:8 | 570 | 2280 | 2,850 | 21,388 | 85,236 | 106,624 |
| Dataset 5 | 1:9 | 285 | 2565 | 2,850 | 10,736 | 95,888 | 106,624 |

Each training process consisted of 100 epochs with a batch size of 64. The mean-square error (MSE) was used as the loss function, and the Adam optimizer with a 0.001 learning rate was used. The training and inference sections were conducted on three computers to comprehensively evaluate the training time costs across different computer tiers. The first computer was equipped with Intel Core i9-13900K CPU and 64 GB RAM, the second computer was equipped with Intel Core i7-1255U CPU and 16 GB RAM, and the third computer was equipped with Intel Core i7-7950H CPU and 16 GB RAM. For the model accuracy to be assessed, the following widely used metrics in regression problems of machine learning are adopted: the mean absolute error (MAE), MSE, and root mean-square error (RMSE). The detailed metrics and the elapsed times for three training trials for each computer are shown in Table IV.

TABLE IV
RESULTS OF METHOD VERIFICATION

| | Training Time (Different | | | | | |
|---|---|---|---|---|---|---|
| | Computers) in Seconds | | | Testing Subset | | |
| | Computer | Computer | Computer | (N_{pred}) Metrics | | |
| Dataset | 1^{a} | 2^{b} | 3^{c} | MAE | MSE | RMSE |
| Dataset 1 | 54 | 149 | 145 | 0.117 | 0.265 | 0.342 |
| Dataset 2 | 44 | 117 | 105 | 0.158 | 0.314 | 0.398 |
| Dataset 3 | 34 | 90 | 85 | 0.185 | 0.330 | 0.430 |
| Dataset 4 | 23 | 60 | 56 | 0.260 | 0.401 | 0.510 |
| Dataset 5 | 11 | 32 | 33 | 0.311 | 0.432 | 0.557 |

Computer 1: Intel Core i9-13900K CPU, 64 GB RAM
Computer 2: Intel Core i7-1255U CPU, 16 GB RAM
Computer 3: Intel Core i7-9750H CPU, 16 GB RAM

FIG. 10 shows the comparison of the measurement and proposed DNN-based linearity prediction methods with different ratios used at P_{PAM}=26 dBm. Plot H is indicative of Load pull contours at P_{PAM}=26 dBm wherein line 1002 is indicative of the measured results and line 1004 is indicate the results of the current method of determining linearity using a DNN 620. Plots I to M illustrate the results of the measured results (1002) and the disclosed DNN implemented method (1004). Plot I illustrates the data ratio 5:5, Plot J illustrates the data ratio of 4:6, Plot K illustrates the data ratio of 3:7, Plot L illustrates a data ratio of 2:8 and Plot M illustrates a data ratio of 1:9. For all the plots the VSWR circle=2.5. The results of the various plots show that the presently disclosed method provides a linearity measurement that is very close to a traditional measurement method.

As shown in Table IV, all MAEs for the tested models are lower than 0.320, ranging from 0.117 to 0.311. The MSEs range from 0.265 to 0.432, and the RMSEs range from 0.342 to 0.557. These results demonstrate the accuracy of the DNN in predicting linearity after it is trained with a certain amount of measured load-pull data. The trends highlight the significant reduction in measurement points without a notable decrease in prediction accuracy. The results indicated that even with the smallest dataset ratio (dataset 5 with a 1:9 ratio), the method maintains acceptable prediction accuracy (RMSE=0.557) while significantly reducing the number of required measurement points to 10,736 from the original 106,624. Additionally, as shown in Table IV, the training times on different computers (computers 1 to 3) indicate that even mid- or low-tier computers can train the network quickly and produce accurate linear predictions (within 3 min). Therefore, the proposed method does not require high-tier computers, and the time used for training and prediction is not significant compared with the total measurement time.

Table V shows the comparison between the measurement times of the traditional and proposed methods, which are based on Pᵢₙ, current, and linearity measurements using the conventional method in FIG. 4. By considering linearity and without linearity measurements, the percentage of time reduction is at least 40% greater (dataset 1 with 5:5) than that of the traditional method. If dataset 5 with a ratio of 1:9 is used, then a time reduction of nearly 80% is achieved. Table V shows only the measurement at the centre frequency channel but corner frequency channels even all channels should be considered. When more bands with APTs are needed, the measurement time becomes more significantly constrained. The findings emphasize the feasibility of reducing the linearity measurement while still accurately predicting linearity. Moreover, the efficiency gains are notable because the time for training a DNN model to predict linearity is significantly faster than that of the traditional approach to measuring linearity. In summary, the proposed DNN-based method effectively saves substantial measurement time while preserving accuracy in linearity prediction. The proposed method is highly feasible and efficient for practical applications in PAM load-pull measurements.

TABLE V
COMPARISON BETWEEN THE MEASUREMENT TIMES

| | Traditional | | | | | |
|---|---|---|---|---|---|---|
| Z_{load, 1}:Z_{load, 2} | Method | 5:5 | 4:6 | 3:7 | 2:8 | 1:9 |
| Nₘₑₐ | 106,624 | 53,334 | 42,430 | 32,043 | 21,388 | 10,736 |
| Mea. time from Nₘₑₐ | 142 | 71.1 | 56.6 | 42.7 | 28.5 | 14.3 |
| (min) | | | | | | |
| N_{pred} | 0 | 53,290 | 64,194 | 74,581 | 85,236 | 95,888 |
| Mea. time from N_{pred} | 0 | 8.88 | 10.70 | 12.43 | 14.21 | 15.98 |
| (min) | | | | | | |
| Total mea. time from | 142 | 80.0 | 67.3 | 55.2 | 42.7 | 30.3 |
| Nₘₑₐ + N_{pred} (min) | | | | | | |
| Time reduction (%) | N/A | 43.73 | 52.68 | 61.20 | 69.95 | 78.69 |

The experimental results confirm that the DNN-based linearity prediction method accurately estimates linearity, significantly reducing the need for direct linearity measurements. The proposed method reduces the overall measurement time while providing accurate PAM load-pull contour plots. When APT is used with different voltages and bias currents in applications, more load-pull contours are required to achieve this optimization. Therefore, the proposed method can significantly reduce the measurement time of this traditional large and time-consuming measurement. This approach ensures the optimal performance and reliability of mobile devices under varying operational scenarios.

Compared with the traditional measurement method, proposed DNN approach has high accuracy in linearity prediction and significantly minimizes the load-pull data measurement time, i.e. from 21 hours to 4.5 hours on general setup. The presently disclosed method and system for determining linearity of a PAM during load pull measurements provides a simple and time-effective method when more load-pull contours from average power tracking with different voltages and bias currents are required.

Although not required, the embodiments described with reference to the Figures can be implemented as an application programming interface (API) or as a series of libraries for use by a developer or can be included within another software application, such as a terminal or personal computer operating system or a portable computing device operating system. Generally, as program modules include routines, programs, objects, components and data files assisting in the performance of particular functions, the skilled person will understand that the functionality of the software application may be distributed across a number of routines, objects or components to achieve the same functionality desired herein.

It will also be appreciated that where the methods and systems of the present invention are either wholly implemented by computing system or partly implemented by computing systems then any appropriate computing system architecture may be utilised. This will include stand alone computers, network computers and dedicated hardware devices. Where the terms “computing system” and “computing apparatus” are used, these terms are intended to cover any appropriate arrangement of computer hardware capable of implementing the function described.

Any reference to prior art contained herein is not to be taken as an admission that the information is common general knowledge, unless otherwise indicated.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be rearranged. A process is terminated when its operations are completed. A process may correspond to a method, a function, a procedure, a subroutine, a subprogram, etc., in a computer program. When a process corresponds to a function, its termination corresponds to a return of the function to the calling function or a main function.

Aspects of the systems and methods described above may be operable or implemented on any type of specific-purpose or special computer, or any machine or computer or server or electronic device with a microprocessor, processor, microcontroller, programmable controller, or the like, or a cloud-based platform or other network of processors and/or servers, whether local or remote, or any combination of such devices.

The term “mobile device” includes, but is not limited to, a wireless device, a mobile phone, a smart phone, a mobile communication device, a user communication device, personal digital assistant, mobile hand-held computer, a laptop computer, wearable electronic devices such as smart watches and head-mounted devices, an electronic book reader and reading devices capable of reading electronic contents and/or other types of mobile devices typically carried by individuals and/or having some form of communication capabilities (e.g., wireless, infrared, short-range radio, cellular etc.).

Furthermore, embodiments may be implemented by hardware, software, firmware, middleware, microcode, or any combination thereof. When implemented in software, firmware, middleware or microcode, the program code or code segments to perform the necessary tasks may be stored in a machine-readable medium such as a storage medium or other storage(s). A processor may perform the necessary tasks. A code segment may represent a procedure, a function, a subprogram, a program, a routine, a subroutine, a module, a software package, a class, or any combination of instructions, data structures, or program statements.

The methods or algorithms described in connection with the examples disclosed herein may be embodied directly in hardware, in a software module executable by a processor, or in a combination of both, in the form of processing unit, programming instructions, or other directions, and may be contained in a single device or distributed across multiple devices. A software module may reside in RAM memory, flash memory, ROM memory, EPROM memory, EEPROM memory, registers, hard disk, a removable disk, a CD-ROM, or any other form of storage medium known in the art. A storage medium may be coupled to the processor such that the processor can read information from, and write information to, the storage medium. In the alternative, the storage medium may be integral to the processor.

One or more of the components and functions illustrated the figures may be rearranged and/or combined into a single component or embodied in several components without departing from the scope of the invention. Additional elements or components may also be added without departing from the scope of the invention. Additionally, the features described herein may be implemented in software, hardware, as a business method, and/or combination thereof.

In its various aspects, embodiments of the invention can be embodied in a computer-implemented process, a machine (such as an electronic device, or a general purpose computer or other device that provides a platform on which computer programs can be executed), processes performed by these machines, or an article of manufacture.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A computer-implemented method of determining linearity of a power amplifier module (PAM) in load pull measurements, comprising:
receiving an input dataset comprising a plurality of load pull parameters;
processing, by a neural network, the input dataset comprising the plurality of load pull parameters; and;
producing an output dataset comprising a linearity of the PAM.

2. The method of claim 1, wherein the linearity of the PAM is determined by inference based on the input parameters.

3. The method of claim 2, further comprising:
feeding the output dataset comprising linearity of the PAM into a full load pull dataset, and;
plotting a load pull contour plot utilising the output dataset and one or more of the load pull parameters from the input dataset.

4. The method of claim 3, wherein the input dataset is processed by a deep neural network (DNN).

5. The method of claim 4, wherein the load pull parameters comprise five parameters, the five parameters are Pᵢₙ, Pₒᵤₜ, Current, VSWR and Phase, wherein:
Pᵢₙ is indicative of the input power to the PAM,
Pₒᵤₜ is indicative of the output power,
Current is the electrical current during a load pull measurement,
VSWR is a voltage standing wave ratio,
Phase is the phase of the current.

6. The method of claim 5 further comprising:
receiving an input dataset comprising a plurality of load pull parameters, wherein the load pull parameters are measured at varying increments of a load impedance coupled to the PAM,
processing the load pull parameters measured at each increment of the load impedance to infer a linearity,
outputting an output dataset comprising a linearity determined for load parameters at each increment.

7. The method of claim 6 further comprising presenting the plotted contour plots on a user interface for use in a mobile front end impedance matching application.

8. The method of claim 7, wherein the method is adapted to reduce the measurement time to determine linearity by at least 40% as compared to a traditional method of determining linearity.

9. A machine learning model for determining linearity of a power amplifier module (PAM) in load pull measurements, in particular for use in the method of claim 8, comprising: a deep neural network (DNN) comprising an input layer, at least three hidden layers and an output layer.

10. The machine learning model of claim 9 wherein the DNN is a lightweight DNN.

11. The machine learning model of claim 10 wherein the DNN comprises four fully connected hidden layers.

12. The machine learning model of claim 11, wherein each hidden layer utilizes a ReLU activation function, and wherein the hidden layers include a descending number of units, wherein the units in each layer form a geometric sequence.

13. The machine learning model of claim 12, wherein the input layer includes five input units, the output layer includes one output unit, and the hidden layers include a descending number of units in successive layers.

14. The machine learning model of claim 13, wherein:
the first hidden layer comprises 128 units,
the second hidden layer comprises 64 units,
the third hidden layer comprises 32 units,
the fourth hidden layer comprises 16 units, and;
wherein each layer is fully connected.

15. A computer-implemented method of training a machine-learning model for determining linearity of a power amplifier module (PAM) in load pull measurements, in particular the machine-learning model of claim 14, comprising:
receiving an input training dataset comprising load pull parameters from conventional load pull measurements; and
using a mean square error as a loss function,
and applying an Adam optimizer with a 0.001 learning rate.

16. A training dataset for use in the method of training a machine-learning model of claim 15, comprising: 100 epochs with a batch size of 64.

17. A data processing apparatus for determining linearity of a power amplifier module (PAM) in load pull measurements comprising means for carrying out the method of claim 16.

18. A system for determining linearity of a power amplifier module (PAM) in load pull measurements comprising:
an input circuit,
a PAM operatively coupled to the input circuit on the input side of the PAM,
an output circuit operatively coupled to an output side of the PAM, wherein the output circuit includes an automated tuner configured to adjust an impedance of the system or the PAM,
a computing apparatus coupled to the output circuit, the computing apparatus comprising a processor and a memory unit, the processor being operatively coupled to the memory unit, wherein the computing apparatus is configured to:
receive an input dataset comprising a plurality of load pull parameters;
process the input dataset comprising the plurality of load pull parameters; and;
produce an output dataset comprising a linearity of the PAM,
wherein the input dataset is processed by a deep neural network (DNN), and;
wherein the load pull parameters comprise Pᵢₙ, Pₒᵤₜ, Current, VSWR and Phase, wherein:
Pᵢₙ is indicative of the input power to the PAM,
Pₒᵤₜ is indicative of the output power,
Current is the electrical current during a load pull measurement,
VSWR is a voltage standing wave ratio,
Phase is the phase of the current, and wherein the input circuit comprises a vector signal generator, pre amplifier and a directional coupler each coupled in series to define the input circuit.

19. A system in accordance with claim 18, wherein the output circuit comprises an attenuator, a directional coupler, a power sensor and a vector signal analyser each coupled in series to define the output circuit,
the output circuit is coupled to the computing apparatus, and;
the PAM is operatively coupled to a power supply.
